(19) United States
(12) Patent Application Publication
(10) Pub. No.: US 2008/0038506 A1
(43) Pub. Date: Feb. 14, 2008

(54) Luminous mesh and method of manufacturing same

(76) Inventors: Helmut Schumacher, Oelde (DE); Ralf Muckermann, Munster (DE); Ralf Rottger, Ennigerloh (DE); Heribert Pieke, Oelde (DE)

Correspondence Address: SMITH LAW OFFICE, 440 SCIENCE DR., SUITE 302, MADISON, WI, 53711, US

(21) Appl. No.: 11/891,734

(22) Filed: Aug. 13, 2007

(30) Foreign Application Priority Data
Aug. 11, 2006 (DE) 10 2006 037 878.4

(51) Int. Cl. B32B 3/00; H01R 43/00; H05K 1/00

(52) U.S. Cl. 428/72; 174/250; 29/825

(57) ABSTRACT

Luminous mesh and method of manufacturing a luminous mesh having a wire mesh comprising warp and weft wires and having luminous elements, wherein the luminous elements are separately disposed on the wire mesh such that the luminous elements can be attached to an already mounted wire mesh.

The present invention relates to a luminous mesh and a method of manufacturing same, and a method of retrofitting wire mesh with luminous elements to thus produce a luminous mesh from an existing wire mesh with simple means.

From the prior art, wire mesh has become known which comprises incorporated light sources.

For example DE 101 27 299 A1 has made known a flat surface in the form of e.g. a wire mesh where one strand of material is manufactured from an optical wave guide and another strand of material, from a different matter. The optical wave guides allow to couple light into the mesh from the edge which light is then emitted throughout the length of the optical wave guide. The drawback therein is that the emission of light cannot be controlled locally since the optical wave guide will always emit light throughout its length. It is another drawback that the optical fibre requires to be interwoven when manufacturing the mesh. Retrofitting existing mesh is virtually impossible.

EP 1 486 598 A2 has made known a metallic mesh and a method of manufacturing a metallic mesh with optical wave guide elements in the shape of glass crystals incorporated in the mesh. The drawback therein is that the glass crystals, which per se do not emit any light, require an external light supply. It is another drawback that retrofitting existing mesh is again virtually impossible.

U.S. Pat. No. 6,793,360 B2 has made known a lighted architectural mesh with light elements interwoven in the mesh. The light elements may e.g. be optical fibres replacing metallic wires. According to this document, retrofitting existing mesh is again virtually impossible.

The internet site “http://www.medienfassade.com/mediamesh.html”, publicly accessible on Aug. 10, 2006, described a metallic mesh where open circular profiles are pushed into the warp of the mesh at defined intervals. Light-emitting diodes are inserted in said open circular profiles. The mesh surface is suitable for reproducing patterns of light. Circular profiles are already interwoven in manufacturing the mesh. It is a drawback therein that the minimum distance of two circular profiles is large. It is another disadvantage that a special mesh must be manufactured. Retrofitting conventional architectural wire mesh is in effect impossible.

In the known prior art, repairing defective light elements or optical wave guide elements is a lengthy procedure. This requires to detension and possibly take down the wire mesh e.g. at the building facade and thereafter individual light elements must be exchanged to replace a defective element.

It is therefore the object of the present invention to provide a luminous mesh which allows to repair defective luminous elements in a fairly simple way. Furthermore it is intended to allow retrofitting existing wire mesh in a relatively simple way.

This object is fulfilled by a luminous mesh having the features of claim 1, by a transparent facade element having the features of claim 19, and by the method of retrofitting a wire mesh according to claim 21.

The luminous mesh according to claim 1 comprises at least one wire mesh and luminous elements, wherein the wire mesh comprises warp and weft wires. The luminous elements of the luminous mesh are separately positioned on the wire mesh such that the luminous elements can be attached to a wire mesh.

The inventive luminous mesh offers many advantages.

One advantage is that according to the invention, an installed wire mesh can be retrofitted with luminous elements such that an existing architectural wire mesh can be modified to form a luminous mesh.

It is a considerable advantage that for repairing defective luminous elements, there is no need for detensioning or dismantling the entire wire mesh to allow repair work.

Furthermore, the wire mesh can be manufactured conventionally for producing the luminous mesh while the known prior art has required extensive steps for interweaving special elements into the mesh.

The luminous elements can in particular be attached to wire mesh that is prefabricated or produced in panels and preferably to a mounted wire mesh. The luminous elements can in particular be provided on the mounted wire mesh to be exchangeable without requiring disassembling.

A preferred more specific embodiment of the invention provides at least part of the luminous elements to be controlled individually and in particular substantially all of the luminous elements can be controlled individually so as to display information on the luminous mesh or to display various light and/or colour patterns. The luminous mesh according to the invention is suitable for displaying information, photos, advertising, art, and for displaying video films or television images or visual image sequences.

Preferably the mesh includes a considerable portion of open surface above 20% and in particular above 40% of the entire wire mesh surface. Preferred embodiments have open surfaces between 55 and 70%, e.g. 64 or 68%.

Such luminous mesh on a building facade offers in addition to displaying information, advertisements, etc., in particular protection from insolation and protection from driving rain, so as to combine a number of functions.

In particular in southern countries, a considerable portion of insolation can thus be held off, while the users or inhabitants of the building can still see the environment through the windows and through the luminous mesh. A high proportion of open surface of the luminous mesh can allow a nearly unimpeded view of the environment out of the building.

A material in particular suitable for the warp and/or weft wires of the wire mesh is metal and preferably steel wherein a non-corroding type may be employed. Using brass and other metallic and non-metallic materials is also conceivable.

In preferred cases some or individual fibres may be plastic-coated to insulate those fibres from other fibres e.g. electrically.

It is also conceivable that a part of the wires consists of a fibre bundle, e.g. being a staple fibre or a rope or the like.

It is also preferred to employ rods as warp and/or weft wires. It is also conceivable to employ rods e.g. in the horizontal direction and e.g. in the vertical direction to employ wires or ropes, e.g. part or all of which being staple fibres.

Although all of the embodiments generally provide for any wire diameter desired, it lies in particular between 0.2 mm and 15 mm. Diameters from 0.5 mm to 5 mm are preferred. It is also conceivable to employ large-diameter tubes or profiled wires.

To support emission of light, optical wave guides may be provided to guide the light emitting from the luminous elements towards one or more separate optical outlets. Optical wave guides may be employed to divert or to bundle existing sunlight or separate light sources in specific directions.

Preferred embodiments of the invention provide one luminous element positioned at a support or a number of luminous elements positioned at one common support. This facilitates assembly since attaching the support allows to attach multiple luminous elements on the wire mesh at the same time.

It is another significant advantage that the luminous elements do not need to be provided in the wire mesh weft direction but the luminous elements may be disposed individually or in groups at any desired warp and/or weft wires.

It is also conceivable to dispose multiple luminous elements at one common support which in turn can be attached at any desired, suitable place of the wire mesh. The support may in particular be provided as a linear, straight component and may, although does not have to, be aligned in the direction of weft.

In contrast to the known prior art, however, alignment in the direction of warp or even diagonal relative to the wire mesh is conceivable. Specific embodiments may advantageously provide to dispose curved or across-corner supports, so as to allow attachment of a support having luminous elements arranged in a predefined pattern e.g. in a circle or ring-shaped or in any predefined contour.

To maintain a high transparency of the luminous mesh and/or to allow a person a largely unimpeded view through the luminous mesh, the supports are preferably made translucent and in particular transparent and neutral in colour. In this way the goal is achieved that in looking through the wire mesh, substantially only the luminous elements are perceived but not the supports.

In preferred embodiments at least one support is provided comprising at least one clamping device which comprises in particular at least one clamping hook or at least one clamping groove or the like. A clamping hook made e.g. of bent wire may be rotatably attached to a warp and/or weft wire, having a receiving section to receive the support. At the other end of the clamping hook a detent may be provided which, after receiving the support in the receiving area, snaps into another warp and/or weft wire to thus fasten the support at the wire mesh.

In another preferred specific embodiment a support is employed having a surface with a stainless steel appearance. The support in particular consists of stainless steel. In the preferably approximately U-shaped support formed as a rail, luminous elements are disposed and preferably arranged on a printed circuit board.

The remaining support space may be poured out with a filler. The filler used is preferably taken from a group of filler materials including, polyester resin, polyurethane resin, polyurethane resin, epoxy resin, silicone resin, silicone, and vinyl ester resin and the like.

Employing a stainless steel support offers the considerable advantage that such supports are unaffected by weather and virtually indestructible.

Placing the luminous elements directly onto a printed circuit board with an electric or electronic circuit for selecting the luminous elements offers the advantage of short distances between control electronics and luminous element. With the luminous elements additionally cast in the support with a filler, the control electronics of the luminous elements will be reliably protected from all weather conditions and from humidity which might cause contact jumps at the control electronics so as to result in malfunction or damage to the electronics.

Where the filler used is transparent, the illuminants of the individual luminous elements may be entirely embedded in the filler material. In all of these cases, the supports equipped with the luminous elements will be compact in structure. The luminous elements are received at or in the supports so as to be damage-proof.

Preferably the filler material used is transparent. Then the luminous elements may be embedded such that the light-emitting surface of the luminous elements is covered in the transparent filler layer. In another preferred embodiment a coloured and in particular dark or even black filler material may be used, which only reaches up to just beneath the light-emitting surface of the luminous elements. In another preferred embodiment the luminous elements are embedded in a dark filler material up to their upper edge, and above that, there is a transparent cover layer consisting of glass or plastic or another filler layer which is transparent.

In another particularly preferred embodiment the clamping means is received at the support loss-proof, or one or more clamping means are fastened at the support e.g. welded or screwed to it. The clamping means may for example extend around the support which is U-shaped in cross-section and comprise a retaining clip at each end. The retaining clips are provided to engage in the wire mesh and to achieve a secure hold of the supports on the wire mesh. For this purpose the retaining clips may be clamped around a warp wire or a weft wire of the wire mesh. A support so equipped with retaining clips may be fastened to the wire mesh as a whole with the luminous elements attached thereto, wherein the retaining clips snap into warp wires or weft wires of the wire mesh and securely retain the support with the luminous elements.

Such a support equipped with loss-proof attached retaining clips is easy to handle and to mount. The retaining clips may be screwed or welded to the support, or the retaining clips may comprise an e.g. square frame to be pushed onto the support such that in operation the retaining clips are fixedly coupled with the support whereas before mounting they are separately pushed onto the support, such that the support and the retaining clips are jointly attached to or removed from the wire mesh.

Alternatively it is also conceivable to fasten the support at the wire mesh by means of a screw, or to provide at the support a clamping groove or multiple clamping grooves whose diameters are matched to the warp and/or weft wires of the wire mesh so as to secure the support to the wire mesh by pushing the clamping groove onto the warp and/or weft wires of the wire mesh.

Alternatively the support may be fastened to the wire mesh by magnetic forces or glue or through a tie wire.

All of these cases allow replacement of defective components with minimum effort since these cases do not require for the basic tension of the mounted wire mesh to be relieved for exchanging luminous elements.

Preferred specific embodiments of the invention provide that at least one luminous element is a light-emitting diode. A luminous element preferably comprises two or three or more light-emitting diodes in different colours which can preferably be controlled individually to accomplish specific, intended colour effects. Alternatively to employing light-emitting diodes, other illuminants may be employed such as light bulbs, luminescent elements or halogen lamps etc.

It is also preferred to employ RGB LEDs or 3-chip systems with colour output or systems with LEDs arranged on a printed circuit board. What is also particularly preferred is, employing organic light-emitting diodes.

In another preferred embodiment, energy supply for at least one luminous element is provided through the wire mesh in which particular warp or weft wires serve as electrical conductors. In this case e.g. the crossing points of the wire mesh are insulated to prevent short circuits. It is also conceivable to provide individual hollow wires such that one or two conductors for power supply may be provided in the interior of the corresponding hollow warp and/or weft wires.

Advantageous embodiments may provide for at least some and in particular substantially all of the luminous elements to be controlled through wireless signals, in particular through radio, infrared, or ultrasonic signals. Preferably each receiver is then provided for one or more luminous elements to pick up the corresponding radio signals and transmit these to the luminous elements associated to the receiver.

In preferred embodiments of the invention the lateral distance of two luminous elements is between approximately 10 and 250 mm, preferably between 25 and 75 mm and in particular approximately 50 mm. At this point we mention that deviations of +20% of the values indicated are conceivable.

In particular for large surfaces, larger lateral distances of e.g. 1 m or more are conceivable.

In particularly preferred embodiments the horizontal distance and the vertical distance of two luminous elements is equal or approximately equal. Equal distance in the sense of the present invention is understood to include a substantially equal distance such that deviations of ±20% are possible and permissible.

In preferred specific embodiments an asymmetric resolution in the horizontal and vertical direction is preferred. It has been found that a higher resolution in the horizontal direction is more important than in the vertical direction such that in the horizontal direction the resolution selected is preferably larger. The ratio of horizontal and vertical resolution is preferably larger 2 and the ratio may be 10 or 20.

All of the embodiments may provide additional optical wave guide elements for diverting the light from the luminous elements and/or incident sunlight. The light from separate lighting fixtures may also be diverted through the optical wave guide elements.

Preferably at least one optical wave guide element is controllable so as to control the light passing through the optical wave guide element. For example adjustable, transparent or reflective lamellae or mirrors may be provided. It is also conceivable to employ liquid crystal displays (LCD systems) or liquid crystal coatings or the like to purposely influence the transparency of a coating. It is also preferred to employ reflectors or lenses for deflection or concentration.

All of the embodiments may provide a transparent covering layer which may consist of glass such as float glass or other types of glass. It is also possible to use synthetic glass such as acrylic glass. The cover glass may be an opaque flint glass and it may be glazed to achieve a homogeneous light spread. Although glazed glass reduces the intensity of emitted light e.g. by 10 or 15%, the homogeneity of the illumination will be enhanced and any moiré effects prevented so as to considerably enhance the viewing quality.

In preferred embodiments of the invention the distance of the warp and weft wires is different wherein the thickness of the warp and weft wires may be similar or even the same.

In the luminous mesh according to the invention or the luminous unit according to the invention there may be employed, instead of a wire mesh, braided wire, knitted wire, or a wire net, on which the luminous elements are disposed.

The invention is also directed at a transparent facade element comprising a transparent carrier unit and luminous elements wherein the luminous elements are separately disposed on the carrier unit so as to allow retrofitting existing facade elements having carrier units with luminous elements.

Although the carrier unit is preferably a wire mesh, it may be formed as knitted wire, braided wire or a wire net or optionally as a perforated plate.

A transparent facade element is preferably provided with a distance between two vertical wires larger than a distance between two horizontal wires from one another.

The transparent facade element preferably provides groups of two, three, four or five vertical wires with the wires in each group positioned tightly adjacent relative to one another, while the distances between one group and the adjacent group is considerably larger than the wire distance within one group.

According to the inventive method of retrofitting a wire mesh with luminous elements, the luminous elements are attached to and fastened on the prefabricated large wire mesh panel e.g. from the rear.

The luminous elements may be attached one by one or they may be preassembled to a separate support which is then mounted on the wire mesh. The method of retrofitting is identically suitable for manufacturing a luminous mesh.

Further advantages and applications can be taken from the exemplary embodiments described below with reference to the Figures.

These show in:

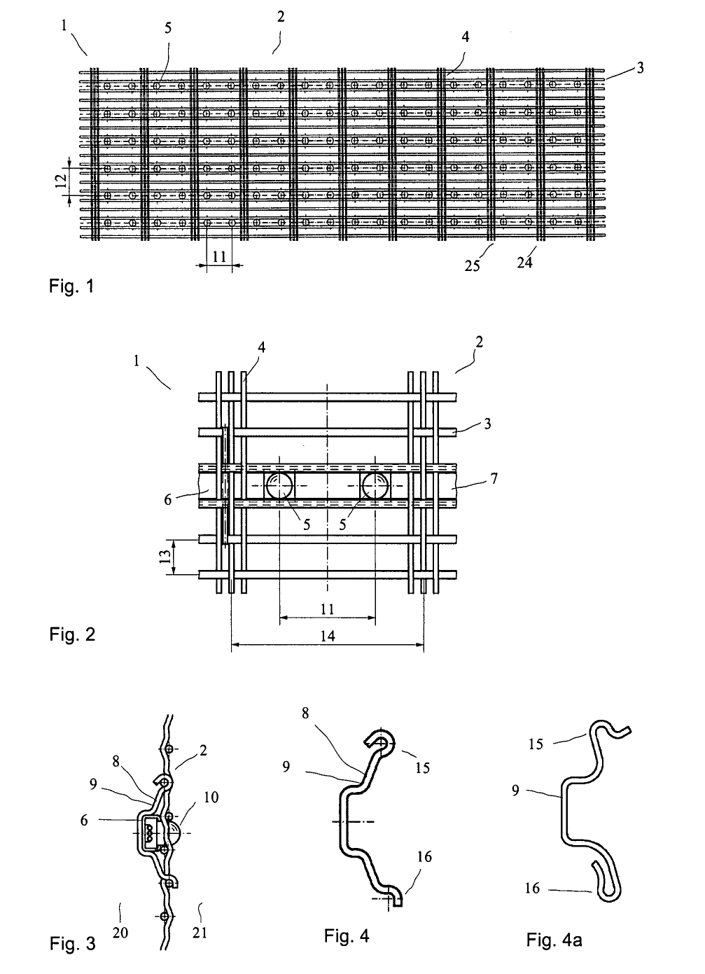

FIG. 1 a front view of a luminous mesh according to the present invention for architectural application;

FIG. 2 an enlarged detail of the front view of the luminous mesh according to FIG. 1;

FIG. 3 a side view of the luminous mesh according to FIG. 2;

FIG. 4 a clamping hook of the luminous mesh according to FIG. 2;

FIG. 4a another clamping hook for a luminous mesh according to FIG. 2;

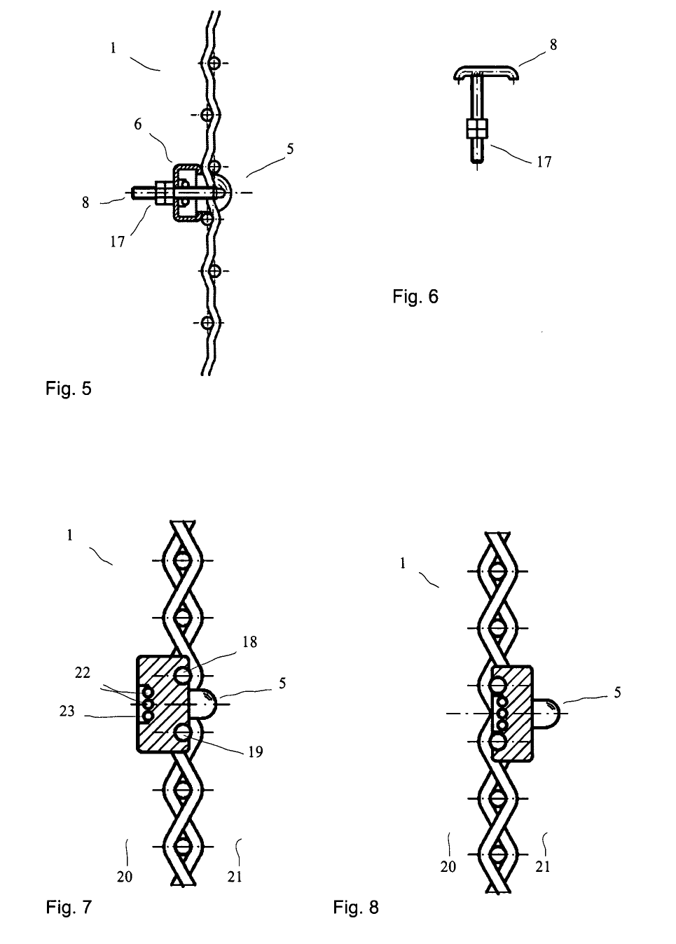

FIG. 5 a side view of another inventive luminous mesh;

FIG. 6 a screw clamp for fastening the luminous elements to the luminous mesh according to FIG. 5;

FIG. 7 a side view of a third inventive luminous mesh;

FIG. 8 a side view of a fourth inventive luminous mesh;

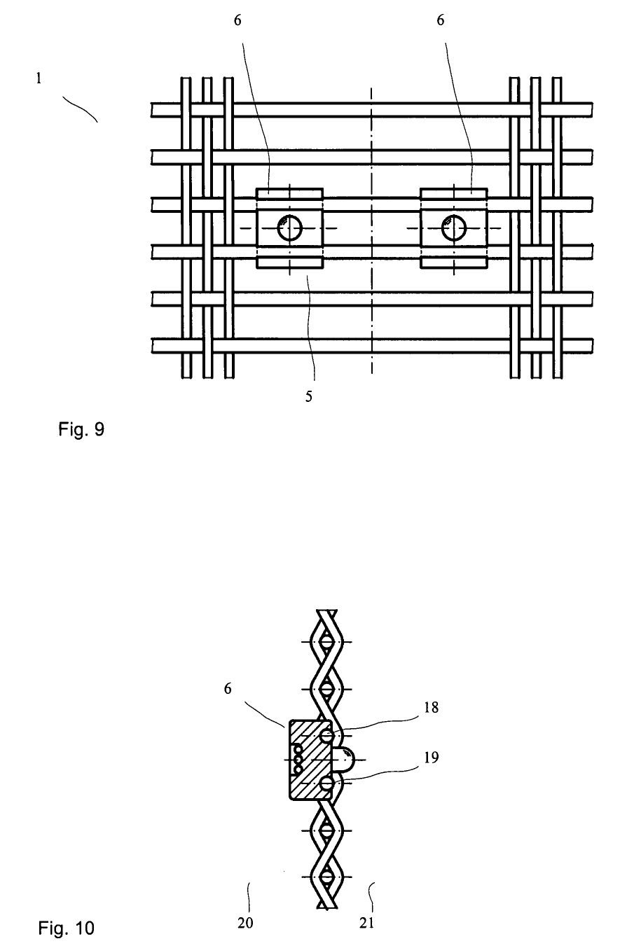

FIG. 9 a front view of a fifth inventive luminous mesh;

FIG. 10 a side view of the luminous mesh according to FIG. 9;

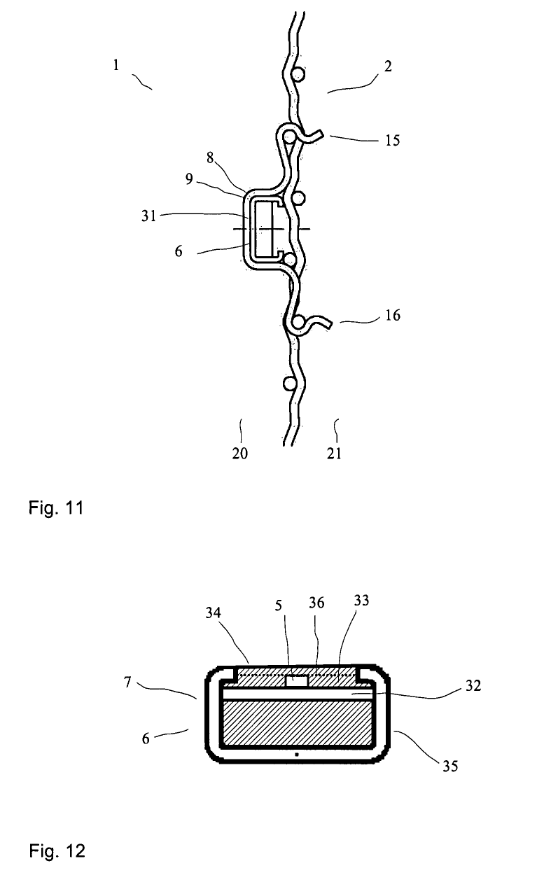

FIG. 11 a side view of another luminous mesh with different clamping means; and

FIG. 12 a cross-section of a support.

FIGS. 1 to 4 illustrate a first embodiment of the luminous mesh 1 according to the invention. FIG. 1 shows a section of a front view of a luminous mesh comprising luminous elements 5 disposed at a wire mesh 2. The wire mesh 2 comprises weft wires 3 and at right angles thereto, warp wires 4.

In the present embodiment, three warp wires 4 each form a group of warp wires 24 and 25. Within the particular groups 24, 25 the individual warp wires are disposed at a very small lateral distance from one another, being only slightly larger than the wire diameter of the warp wires, while the lateral distance from one group 24 to the next group 25 is considerably larger by a factor of more than 10 in the present embodiment. This is one feature by which to achieve a high proportion of open luminous mesh to thus allow an only slightly impeded view through the luminous mesh 1.

In this embodiment the horizontal distance 11 of the individual luminous elements approximately equals the vertical distance 12 of two luminous elements, said luminous elements being disposed approximately equidistantly over the surface of the luminous mesh 1. Such equidistant positioning of the luminous elements makes the luminous mesh 1 particularly suitable to illustrate geometric images, or also non-moving or moving pictures or shapes, and photos or video films. An asymmetric resolution is conceivable as well with the horizontal resolution preferably being higher than the vertical resolution.

The distance between the present luminous elements 5 is approximately 50 mm although in other embodiments it may be 25 mm, 50 mm, 100 mm, or 200 mm (approximately 8 inches). The present distance of 50 mm (circa 2 inches) achieves a resolution of 320×240 image points for a mesh size of 16 m×12 m, and a VGA resolution of 640×480 image points for a mesh size of 32 m×24 m. This surface size is available at the facades of many industrial or other high-rise buildings so as to allow widespread use. What is also conceivable is video screens in stadia or in public squares or the like to be used for image transmission in sports or other mass events.

The individual luminous elements 5 in the embodiment according to FIGS. 1 to 4 are mounted to a support 6 designed as a rail 7. The rail 7 is fastened to the wire mesh 2 by means of a clamping means 8 configured as a fastening hook 9. One end 15 of the fastening hook 9 is pivotally attached to a weft wire 3, and the other end 16 of the fastening hook 9 is clamped to another weft wire 3 of the wire mesh 2, while the rail 7 is received in a receiving section of the fastening hook 9 where it is clamped to the luminous mesh 1.

FIG. 4a shows a variant of the hook 9 which is hooked into the mesh at its end 16 and with its other end 15, snapped into the mesh for fastening the support 6.

The rail 7 with the luminous elements 5 is mounted to the rear of the wire mesh 2. Parts of the individual luminous elements protrude through open spots in the wire mesh 2. This provides good protection of the luminous elements 5 from outside influences such as hailstorm or vandalism, in particular with the luminous elements mounted still farther back than illustrated in FIG. 3. Specific configurations may provide separate jalousies or roller blinds to protect the luminous elements and the luminous mesh when not used.

The luminous mesh 1 according to the invention is suitable for indoor and outdoor use. An interior wall may for example be provided with a large luminous mesh panel showing TV images when lighted while when unlighted, it may serve as a high quality wall facing. More specific embodiments may provide for smaller electronic luminous elements to be employed so as to achieve a higher density of the luminous points.

Where the luminous mesh 1 is employed as a transparent facade element 1, application will primarily be outdoor.

A top view of the exemplary embodiment according to FIGS. 5 and 6 substantially corresponds to the top view of FIG. 1, such that the discussion of the variant illustrated in FIGS. 5 and 6 only includes the differences from the previous embodiment. In the side view of a luminous mesh 1 illustrated in FIG. 5, the luminous elements 5 are also received in a support 6 which may again be configured as a rail 7.

In contrast to the previous embodiment, the support 6 is fastened to the luminous mesh 1 by means of a clamping means 8 having a screw thread 17. For the purpose of fastening, the support 6 is clamped to the mesh by way of the retaining clip of the clamping means 8.

The variant illustrated in FIG. 7 has a support 6 comprising clamping grooves 18 and 19, which are pushed onto and clamped to warp or weft wires of the wire mesh. This option of fastening also achieves a secure seat of the support 6 or the luminous elements 5 on the wire mesh. The diameter of the clamping grooves 18 and 19 is matched to the diameters of the wires (weft wires, warp wires).

One can clearly recognize three lines on the rear of the support 6 in FIG. 7. In this specific case, two of the three lines serve as power supply. The third line together with the ground of the power supply serves as a data line. Data communication may be implemented as a bus system, in particular as an auto addressable series connection. A separate, conventional wiring of each single luminous element is possible as well.

In another embodiment of the system, one or more luminous elements emitting one or more colours each, may be placed on one common printed circuit board. These printed circuit boards are then connected with one another and with the control by way of a four-line system. In this case, two lines are provided for power supply and two lines, as data lines.

Both of the systems may be configured as twin-conductor systems where data signals are also modulated onto the power transmission conductors. Data communication may likewise occur by means of optical wave guides.

In another preferred embodiment, control and/or power supply of at least one luminous element or multiple luminous elements occurs through separate lines with the luminous elements interconnected in particular through a bus system.

In the embodiment illustrated in FIG. 7, the support is provided on the rear 20 of the wire mesh 2 of the luminous mesh 1 with the luminous element 5 protruding through the wire mesh, such that the luminous elements 5 protrude as far as the front face 21 of the wire mesh. Viewed from the front, the luminous elements 5 disposed in the transparent rails 7 are hardly noticeable in a switched-off state.

The embodiment illustrated in a side view in FIG. 8 shows a wire mesh 1 with the support 6 provided, not on the rear 20 of the luminous mesh 1 but on the front 21 of the luminous mesh 1. In this embodiment the rail or the support 6 is also pushed or clipped onto wires of the wire mesh.

In the embodiment illustrated in FIGS. 9 and 10, each luminous element 5 is provided with a separate support 6 which are then attached to the weft or the warp wires of the wire mesh in that said support is clamped to the wires of the luminous mesh 1 by means of the fastening grooves 18 and 19.

FIG. 11 shows another embodiment in a side view. The rear face 20 of a luminous mesh 1 is provided with a support 6 at the luminous mesh 1 provided as a U-shaped, profiled rail. The rail 6 bears against the wire mesh 2, extending over the width of one or more wire mesh segments which typically comprise a mesh width between approximately 50 cm and 10 m.

In this embodiment the support 6 is also retained to the wire mesh 2 in multiple places by way of clamping means 8 configured as retaining clips or hooks 9. Herein both ends 15 and 16 of the fastening hook 9 are shaped the same. For mounting, the rail 7 is held to the provided position at the wire mesh 2, and the hooks 9 are placed over the rail 7 at predefined distances and clipped to the wire mesh 2 to thus establish a firm connection between the rail 7 and the wire mesh 2.

In another embodiment the hooks 9 are secured to the rail 7 at predefined distances of e.g. 30 cm or 50 cm or the like, such that the entire rail 7 with the hooks 9 is fixed or clipped onto the wire mesh.

One advantage of such a configuration is that only the rail 7 needs to be used for mounting since the hooks 9 are already incorporated in the rail. In both of the cases described above, simply clipping the rails on the wire mesh 2 allows to transform a normal wire mesh on a facade into a luminous mesh, or by way of removing the rails, a luminous mesh is transformed into a normal wire mesh.

Another possible configuration of the rail 7 is shown in cross-section in FIG. 12. The U-shaped profile of the rail 7 receives a printed circuit board 32 inserted into it which in the illustration according to FIG. 12 extends approximately over the entire free width between the U-legs of the U-profile. A smaller width is conceivable as well.

The printed circuit board 32 accommodates the circuits provided for controlling the luminous elements 5 with the luminous elements 5 being positioned at predefined distances. The printed circuit board 32 thus forms a compact unit accommodated to be well protected in the rail 7. As a protection from humidity and from mechanical influences the remaining space in the rail is filled up with a filler material 33 which in the present embodiment may consist of different materials and may be e.g. an acrylic resin or a silicone.

The outer surface 35 of the rail 7 in particular has an appearance of stainless steel. Preferably the rail 7 is made of stainless steel to generate high stability and an appearance uniform with the wire mesh 2, which is also preferably made of stainless steel. Employing stainless steel rails enables the supports to perfectly adjoin the wire mesh.

The dotted line 36 in FIG. 12 shows the position of a possible covering layer which, being a separate layer, may be made of glass or plastic. An upper layer of a transparent filler material is also possible and preferred while the bottom layer may consist of a dark or black filler material.

1. A luminous mesh comprising at least one wire mesh and luminous elements, the wire mesh comprising weft and warp wires, characterized in that the luminous elements are separately disposed on the wire mesh, such that the luminous elements can be attached to an already mounted wire mesh.

2. The luminous mesh according to claim 1, wherein at least the majority of the luminous elements can be controlled individually to output visual information on the wire mesh.

3. The luminous mesh according to claim 1, wherein at least one luminous element is disposed on a support.

4. The luminous mesh according to claim 1, wherein the support is configured to be transparent.

5. The luminous mesh according to claim 3, wherein the support comprises a rail.

6. The luminous mesh according to claim 5, wherein the luminous elements are disposed on a printed circuit board received in the rail.

7. The luminous mesh according to claim 6, wherein the printed circuit board in the rail is cast into and embedded in a filler material.

8. The luminous mesh according to claim 3, wherein the support comprises at least one clamping means which comprises at least one hook.

9. The luminous mesh according to claim 8, wherein the hook is connected with the support to be loss-proof.

10. The luminous mesh according to claim 3, wherein the support comprises at least one clamping means which comprises at least one clamping groove.

11. The luminous mesh according to claim 3 wherein the support is attached to the wire mesh by a fastening method which comprises clamps, screws, glue, magnetic forces, or are pegged or clipped on.

12. The luminous mesh according to claim 1, wherein at least one luminous element comprises at least two luminous units in different colour characteristics.

13. The luminous mesh according to claim 1, wherein control of at least one luminous element is provided via the wire mesh.

14. The luminous mesh according to claim 1, wherein control of at least one luminous element occurs via separate lines.

15. The luminous mesh according to claim 1, wherein the luminous elements are interconnected through a bus system.

16. The luminous mesh according to claim 1, wherein the lateral distance of two luminous elements is between 25 mm and 250 mm.

17. The luminous mesh according to claim 1, wherein the horizontal distance and the vertical distance of two luminous elements is the same.

18. The luminous mesh according to claim 1 employing instead of a wire mesh, a wire unit taken from a group of units of wire comprising, braided wire, knitted wire, and a wire net, on which the luminous elements are disposed.

19. A transparent facade element comprising a transparent carrier unit and luminous elements, characterized in that the luminous elements are separately disposed on the carrier unit, such that retrofitting existing facade elements, which are equipped with carrier units, with luminous elements is possible.

20. The transparent facade element according to claim 19, wherein the carrier unit is taken from a group of carrier units comprising a wire mesh, knitted wire, braided wire, and a wire net.

21. A method of retrofitting a wire mesh with luminous elements wherein the luminous elements are attached to and fastened on the prefabricated large wire mesh panel.

22. The method according to claim 21, wherein multiple luminous elements are provided on a support which is then attached to the wire mesh.

23. The method of claim 21, wherein the support is clipped on.
